(19) United States
(12) Patent Application Publication
(10) Pub. No.: US 2024/0140725 A1
(43) Pub. Date: May 2, 2024

(54) Article Transport Facility

(71) Applicant: Daifuku Co., Ltd., Osaka-shi (JP)

(72) Inventors: Toshihito Ueda, Hinocho (JP); Shota Inden, Hinocho (JP); Akira Suzuki, Hinocho (JP)

(21) Appl. No.: 18/383,074

(22) Filed: Oct. 24, 2023

(30) Foreign Application Priority Data
Oct. 26, 2022 (JP) 2022-171551

(51) Int. Cl. B65G 43/10

(52) U.S. Cl. CPC B65G 43/10

(57) ABSTRACT

An article transport facility includes at least one transport vehicle, a travel path, a plurality of section control devices, and a superior control device. The travel path includes a plurality of recording points. The plurality of section control devices are each configured to (i) record a control state of the at least one transport vehicle at each recording point in a control region controlled by the section control device, as recording information associated with the each recording point, (ii) generate transmission information including a plurality of pieces of the recording information for the each recording point, and (iii) transmit the transmission information to the superior control device.

### CROSS-REFERENCE TO RELATED APPLICATION

This application claims priority to Japanese Patent Application No. 2022-171551 filed Oct. 26, 2022, the disclosure of which is hereby incorporated by reference in its entirety.

### BACKGROUND OF THE INVENTION

### 1. Field of the Invention

The present invention relates to an article transport facility including a transport vehicle for transporting an article.

### 2. Description of Related Art

There has been known an article transport facility including a transport vehicle for transporting an article, a section control device, and a superior control device. Reference signs in parentheses in the description of Description of the Related Art are those described in Patent Literature 1 (Japanese Unexamined Patent Application Publication No. 2015-176497). Patent Literature 1 discloses an article transport facility including a transport vehicle (a traveling vehicle) for transporting an article, a section control device (2), and a superior control device (3) for controlling a plurality of section control devices (2). The section control device (2) instructs a transport vehicle (a traveling vehicle) in a section controlled by the section control device (2) itself to travel, based on a traveling request received from the superior control device (3).

In the article transport facility of Patent Literature 1, the section control device (2) generates travel experience information on a transport vehicle (a traveling vehicle) in the section controlled by the section control device (2) itself and transmits it to the superior control device (3). The superior control device (3) receives and collects pieces of travel experience information on all transport vehicles in an area from all section control devices (2) in the area. This accordingly causes such a problem. That is, in a case where some sort of abnormality has occurred in a given point, for example, it is necessary to find necessary information from all the pieces of travel experience information collected by the superior control device (3) to check the control state of a transport vehicle (traveling vehicle) in the given point, and this checking operation is not easy.

### SUMMARY OF THE INVENTION

In view of the foregoing, it is desired to attain an article transport facility that facilitates an easy check of the control state of a transport vehicle in a given point in a superior control device.

An article transport facility according to this disclosure is an article transport facility including: at least one transport vehicle configured to transport an article; a travel path on which the at least one transport vehicle travels, the travel path being divided into a plurality of control regions; a plurality of section control devices each provided for a corresponding control region out of the plurality of control regions and configured to control passage of the at least one transport vehicle in the corresponding control region; and a superior control device configured to control the plurality of section control devices. The travel path includes a plurality of recording points. The plurality of section control devices are each configured to (i) record a control state of the at least one transport vehicle at each recording point in the corresponding control region as recording information associated with the each recording point, (ii) generate transmission information including a plurality of pieces of the recording information for the each recording point, and (iii) transmit the transmission information to the superior control device by the each recording point.

In this configuration, the section control device gathers up control states in the whole control region controlled by itself for each recording point to generate transmission information and transmits the transmission information to the superior control device per recording point. With such a configuration, information to be received on the superior control device side is information collective per recording point, so that the control state of the transport vehicle at each recording point is easily checked in the superior control device. Further, it is possible to restrain the amount of information transmitted and received at a time between the section control device and the superior control device, thereby making it possible to reduce a burden to a communication line.

### BRIEF DESCRIPTION OF THE DRAWINGS

FIG. 1 is a plan view of an article transport facility;

FIG. 2 is a control block diagram of the article transport facility in FIG. 1;

FIG. 3 is a view illustrating a specific section of a control region in FIG. 1;

FIG. 4 is a view to describe transmission information to be transmitted by a section control device in FIG. 3;

FIG. 5 is a view to describe recording information to be recorded by the section control device in FIG. 3;

FIG. 6 is a plan view illustrating a specific section according to another embodiment;

FIG. 7 is a plan view illustrating a specific section according to another embodiment;

FIG. 8 is a plan view illustrating a specific section according to another embodiment; and

FIG. 9 is a plan view illustrating a specific section according to another embodiment.

### DESCRIPTION OF THE INVENTION

An embodiment of an article transport facility will be described below with reference to drawings.

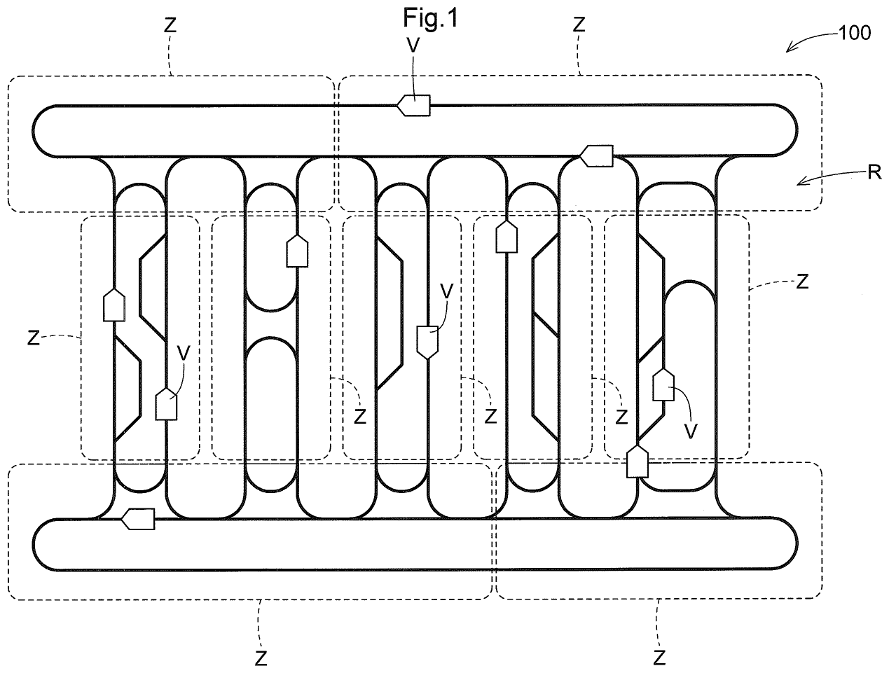

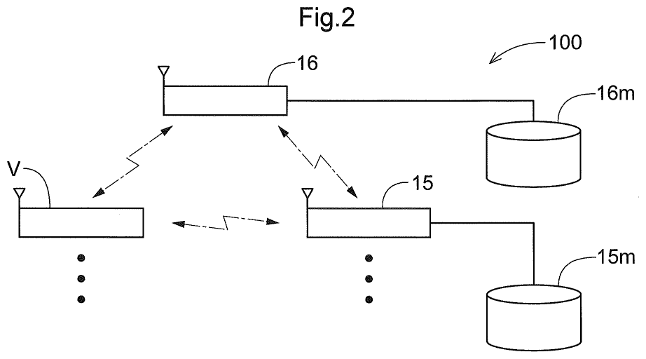

FIG. 1 is a view illustrating an example of an article transport facility 100. FIG. 2 is a view illustrating an example of a control block of the article transport facility 100. The article transport facility 100 includes a transport vehicle V for transporting an article. Examples of the transport vehicle V include an unmanned transport vehicle traveling along a floor face, a ceiling transport vehicle traveling near a ceiling, and the like. Examples of the article managed by the article transport facility 100 include a so-called FOUP (Front Opening Unified Pod) that is a wafer storage container, a so-called reticle pod that is a reticle storage container for storing reticles, and the like. In the present embodiment, the article transport facility 100 includes a plurality of transport vehicles V. Each of the plurality of transport vehicles V includes unique transport vehicle identification information Fv.

The article transport facility 100 includes a travel path R along which the transport vehicle V travels. In the present embodiment, a first path R1 and a second path R2 are paths along which the transport vehicle V travels unidirectionally from the upstream side toward the downstream side. The travel path R is divided into a plurality of control regions Z. In the control region Z, passage of the transport vehicle V is controlled by a section control device 15 illustrated in FIG. 2.

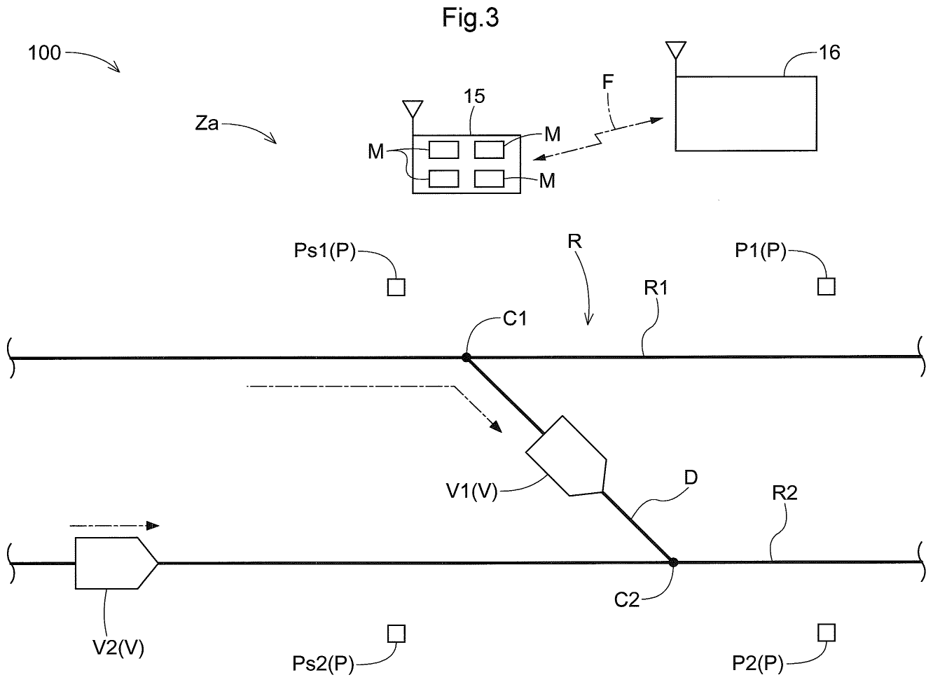

FIG. 3 is a view illustrating an example of a specific section Za included in the control region Z. In the present embodiment, each of the plurality of control regions Z includes the specific section Za. The specific section Za includes the first path R1 and the second path R2 not intersecting with each other, and a connection path D connecting a first connecting part C1 in the first path R1 to a second connecting part C2 in the second path R2. One specific section Za or a plurality of specific sections Za may be included in each of the plurality of control regions Z.

A plurality of recording points P is set along the travel path R. In the present embodiment, each of the plurality of recording points P has unique point identification information Fp. Examples of the recording point P include a passage point as a sign indicating that the transport vehicle V has passed the specific section Za, a stop point as a sign in a case where the transport vehicle V stops just before the connection path D, and the like.

In the present embodiment, a first passage point P1 as one of the recording points P is set on the downstream side from the first connecting part C1 in the first path R1. Further, a first stop point Ps1 as one of the recording points P is set on the upstream side from the first connecting part C1 in the first path R1.

In the present embodiment, a second passage point P2 as one of the recording points P is set on the downstream side from the second connecting part C2 in the second path R2. Further, a second stop point Ps2 as one of the recording points P is set on the upstream side from the second connecting part C2 in the second path R2.

In the present embodiment, the first passage point P1 is associated with the second passage point P2 as associated point information Fm. Further, the second passage point P2 is associated with the first passage point P1 as associated point information Fm. In a case where the section control device 15 gives passage permission or a standby command to the transport vehicle V to pass through one recording point P out of the first passage point P1 and the second passage point P2, for example, these pieces of associated point information Fm are used to search for the other recording point P.

As illustrated in FIG. 2, the article transport facility 100 is provided for a plurality of control regions Z and includes the section control device 15 configured to control passage of the transport vehicle V in the control region Z controlled by the section control device 15 itself, and the superior control device 16 configured to control a plurality of section control devices 15. In the present embodiment, the superior control device 16 gives a transport command to the transport vehicle V, and the transport vehicle V transports the article based on the transport command thus given.

In the present embodiment, the section control device 15 is configured such that, in a case where the transport vehicle V is to pass through the specific section Za provided in the control region Z controlled by the section control device 15 itself, the section control device 15 determines whether or not the transport vehicle V is permissible to pass through the specific section Za. Further, the section control device 15 is configured to acquire a passage completion notice when the transport vehicle V has passed through the recording point P. In the present embodiment, the transport vehicle V, the plurality of section control devices 15, and the superior control device 16 are configured to be wirelessly communicable with each other but may be configured to be communicable with each other by wired communication.

The following describes an example of a passage control on the transport vehicle V by the section control device 15 with reference to FIG. 3. In the present embodiment, in a case where the transport vehicle V travels along the first path R1 through the first connecting part C1, the transport vehicle V requests the section control device 15 to give first passage permission that is passage permission to pass through the first passage point P1, on the upstream side from the first connecting part C1. In a case where the transport vehicle V acquires the first passage permission, the transport vehicle V passes through the first connecting part C1 and is directed toward the first passage point P1, but in a case where the transport vehicle V does not acquire the first passage permission, the transport vehicle V stops on the upstream side from the first connecting part C1. In the example illustrated herein, in a case where a transport vehicle V1 does not acquire the first passage permission, the transport vehicle V1 stops at the first stop point Ps1. Further, while the transport vehicle V1 is traveling on the upstream side from the first stop point Ps1 in the first path R1, the transport vehicle V1 requests the section control device 15 to give the first passage permission or second passage permission (described later).

In the present embodiment, in a case where the transport vehicle V travels along the second path R2 through the second connecting part C2, the transport vehicle V requests the section control device 15 to give the second passage permission as passage permission to pass through the second passage point P2, on the upstream side from the second connecting part C2. In a case where the transport vehicle V acquires the second passage permission, the transport vehicle V passes through the second connecting part C2 and is directed toward the second passage point P2, but in a case where the transport vehicle V does not acquire the second passage permission, the transport vehicle V stops on the upstream side from the second connecting part C2. In the example illustrated herein, in a case where a transport vehicle V2 does not acquire the second passage permission, the transport vehicle V2 stops at the second stop point Ps2. While the transport vehicle V is traveling on the upstream side from the second stop point Ps2 in the second path R2, for example, the transport vehicle V requests the section control device 15 to give the first passage permission or the second passage permission. In the example illustrated herein, while the transport vehicle V2 is traveling on the upstream side from the second stop point Ps2 in the second path R2, the transport vehicle V2 requests the section control device 15 to give the second passage permission.

In the present embodiment, in a case where the section control device 15 gives the first passage permission to the transport vehicle V, the transport vehicle V is allowed to occupy the first passage point P1 based on the first passage permission. After the transport vehicle V has passed through the first passage point P1, the transport vehicle V transmits a passage completion notice to the section control device 15. After the section control device 15 has received the passage completion notice from the transport vehicle V, the section control device 15 releases the occupation of the first passage point P1 by the transport vehicle V based on the passage completion notice. Note that the first passage point P1 may be configured to transmit the passage completion notice to the section control device 15, instead of the transport vehicle V.

In the present embodiment, in a case where the section control device 15 gives the second passage permission to the transport vehicle V, the section control device 15 allows the transport vehicle V to occupy the second passage point P2 based on the second passage permission. After the transport vehicle V has passed through the second passage point P2, the transport vehicle V transmits a passage completion notice to the section control device 15. After the section control device 15 has received the passage completion notice from the transport vehicle V, the section control device 15 releases the occupation of the second passage point P2 by the transport vehicle V based on the passage completion notice. Note that the second passage point P2 may be configured to transmit the passage completion notice to the section control device 15, instead of the transport vehicle V.

In the present embodiment, in a case where the section control device 15 is requested, from the transport vehicle V, to give permission to travel from the first path R1 to the connection path D, under the condition that an unoccupied state where both the first passage point P1 and the second passage point P2 are not occupied by other preceding transport vehicles V is established, the section control device 15 permits the transport vehicle V to travel from the first path R1 to the connection path D and allows the transport vehicle V thus permitted to travel to occupy both the first passage point P1 and the second passage point P2. In the example illustrated herein, the transport vehicle V1 occupies both the first passage point P1 and the second passage point P2, and the transport vehicle V2 cannot acquire the second passage permission and stops at the second stop point Ps2. In the present embodiment, after the transport vehicle V has passed through the second passage point P2, the transport vehicle V transmits a passage completion notice to the section control device 15. After the section control device 15 has received the passage completion notice from the transport vehicle V, the section control device 15 releases the occupation of the first passage point P1 and the second passage point P2 by the transport vehicle V based on the passage completion notice.

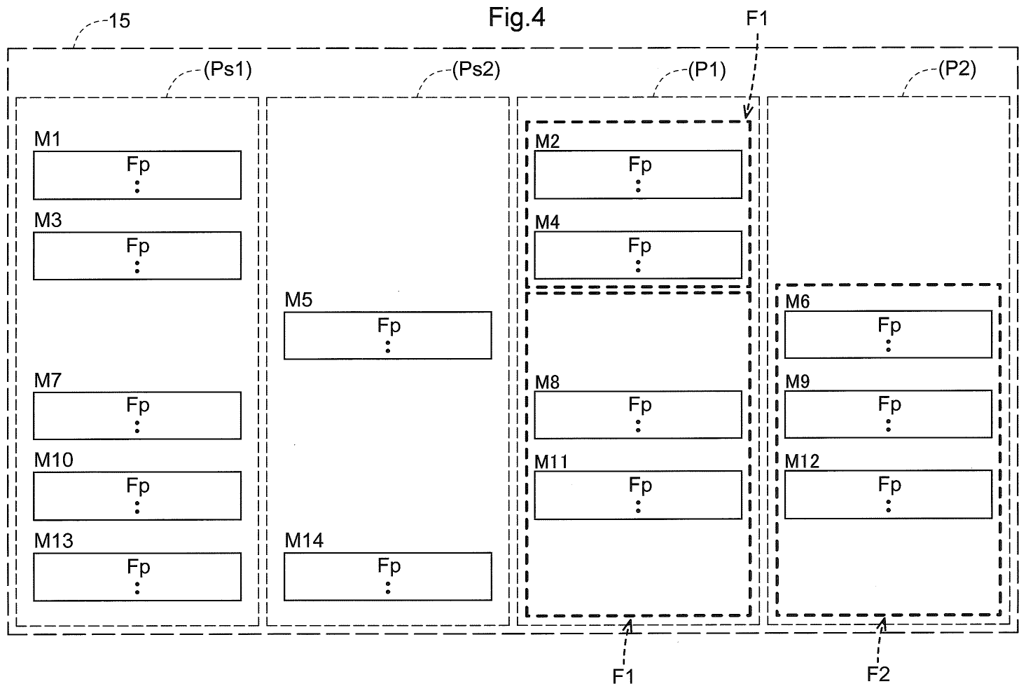

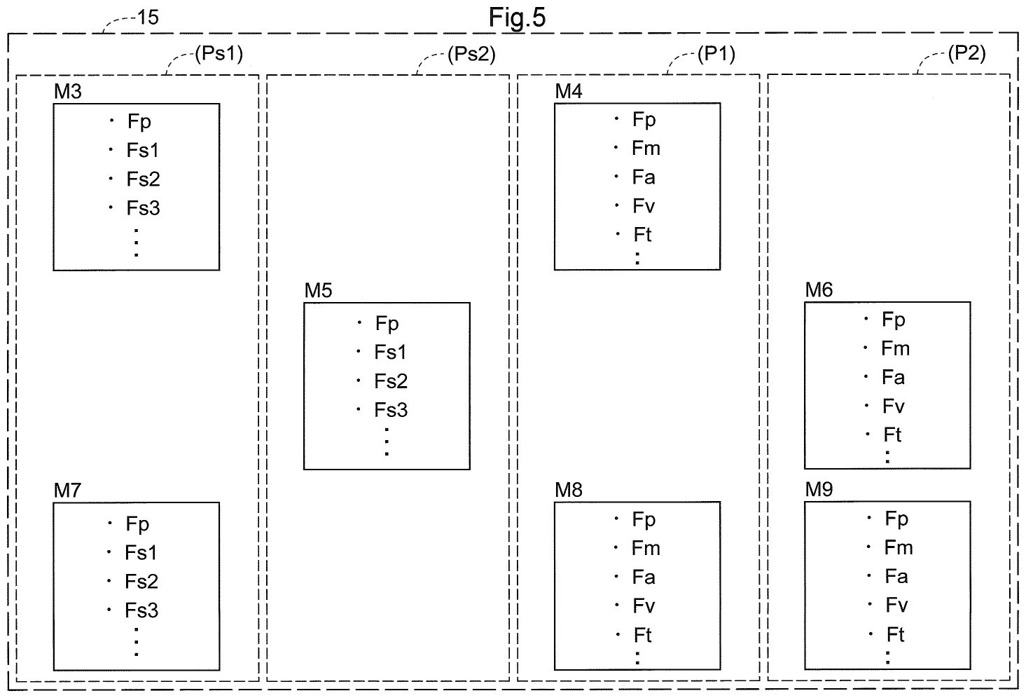

FIG. 4 is a view illustrating examples (from M1 to M14) of recording information M recorded by the section control device 15 and examples (F1, F2) of transmission information F to be transmitted by the section control device 15. FIG. 5 is a view to describe examples (from M3 to M9) of the recording information M in FIG. 4 in detail.

The section control device 15 records the control state of the transport vehicle V related to each of the plurality of recording points P in the control region Z controlled by the section control device 15 itself, as recording information M associated with the each of the plurality of recording points P. Further, the section control device 15 gathers up a plurality of pieces of recording information M for each recording point P to generate transmission information F and transmits the transmission information F per recording point to the superior control device 16. With this configuration, information to be received on the superior control device 16 side is information collective per recording point P, so that the control state of the transport vehicle V at each recording point P is easily checked in the superior control device 16. Further, it is possible to restrain the amount of information transmitted and received at a time between the section control device 15 and the superior control device 16, thereby making it possible to reduce a burden to a communication line.

Examples of the control state of the transport vehicle V to be recorded as the recording information M include, for example, passage permission information indicating that the section control device 15 has given passage permission to the transport vehicle V, standby command information indicating that the section control device 15 has given a standby command to the transport vehicle V, passage request information indicating that the section control device 15 has acquired a passage request from the transport vehicle V, and passage completion information indicating that the transport vehicle V has passed through the recording point P.

Referring back to FIG. 2, in the present embodiment, the section control device 15 stores the recording information M in a storage section 15m provided in the section control device 15. As the recording information M, all pieces of recording information M in the control region Z controlled by the section control device 15 may be recorded in chronological order or may be recorded per recording point P. In a case where a plurality of pieces of recording information M is recorded per recording point P in the section control device 15, the plurality of pieces of recording information M thus recorded per recording point P is gathered up per recording point P immediately, so that transmission information F is easily generated and transmitted. In the examples illustrated in FIGS. 4 and 5, pieces of recording information M (from M1 to M14) are recorded per recording point P (Ps1, Ps2, P1, P2).

In the present embodiment, the section control device 15 stores occupation state information indicating whether each passage point (P1, P2) is in an occupied state or in an unoccupied state, in the storage section 15m provided in the section control device 15. The section control device 15 gives passage permission to the transport vehicle V based on the occupation state information stored in the storage section 15m. Further, the section control device 15 is configured to update the update occupation state information stored in the storage section 15m at any time in accordance with the state of the specific section Za.

In the present embodiment, the superior control device 16 stores transmission information F in a storage section 16m provided in the superior control device 16. Further, although not illustrated herein, the superior control device 16 includes an input device such as a touch panel or a keyboard, and an output device such as a monitor, a printer, and a speaker, so that an operator performs a checking operation to check the control state of the transport vehicle V.

As illustrated in FIG. 4, in the present embodiment, an accumulation period is set for each of the plurality of recording points P. The section control device 15 generates transmission information F by gathering up pieces of recording information M related to each recording point P every time the accumulation period elapses, and the section control device 15 transmits the transmission information F to the superior control device 16. This allows the superior control device 16 to automatically acquire the transmission information F continuously. Further, since the accumulation period as a sign for transmission of the transmission information F is set per recording point P, the transmission information F is easily transmitted to the superior control device 16 at respective different timings of the plurality of recording points P. Accordingly, it is possible to restrain the amount of information transmitted and received at a time between the section control device 15 and the superior control device 16.

In the present embodiment, in a case where the transport vehicle V is made stand by in a given recording point P, the section control device 15 records standby command information indicating that a standby command has been given to the transport vehicle V, as recording information M in association with the given recording point P where the transport vehicle V has been made stand by. Examples of the standby command information include point identification information Fp, stop starting time information Fs1 indicating a time when a standby command has been given, stopping time information Fs2 as an elapsed time from the standby start, and stopped transport vehicle identification information Fs3 on the transport vehicle V that has received the standby command. Note that, as the stop starting time information Fs1, a record time when the standby command information has been recorded as the recording information M may be used. The standby command information is recorded as the recording information M in a time when the section control device 15 has given the standby command to the transport vehicle V, for example. Further, for example, the stopping time information Fs2 may be recorded as the recording information M at a given cycle.

In the present embodiment, in a case where the section control device 15 permits the transport vehicle V to pass through a given recording point P, the section control device 15 records passage permission information Fa indicating that passage permission has been given to the transport vehicle V, as recording information M in association with the given recording point P through which the transport vehicle V has been permitted to pass. The passage permission information Fa may be point identification information Fp, transport vehicle identification information Fv, or permission time information Ft (described later). Further, the passage permission information Fa may include the abovementioned standby command information, the abovementioned passage request information, and the like.

In the present embodiment, in a case where the section control device 15 permits the transport vehicle V to pass through a given recording point P, the section control device 15 records, as recording information M, point identification information Fp on the given recording point P through which the transport vehicle V has been permitted to pass, in association with transport vehicle identification information Fv on the transport vehicle V permitted to pass through the given recording point P, and permission time information Ft indicative of a time when the permission has been given. Note that, as the permission time information Ft, a record time when the passage permission information Fa has been recorded as the recording information M may be used.

In the present embodiment, in a case where the section control device 15 gives passage permission to the transport vehicle V traveling along the first path R1 to pass through the first passage point P1, the section control device 15 records passage permission information Fa indicating that the passage permission has been given to the transport vehicle V, as recording information M in association with the first passage point P1. In the example illustrated herein, in a case where the section control device 15 gives passage permission to the transport vehicle V traveling along the first path R1 to pass through the first passage point P1, the section control device 15 records, as the recording information M, transport vehicle identification information Fv on the transport vehicle V receiving the passage permission and permission time information Ft indicative of a time when the passage permission has been given, in association with point identification information Fp on the first passage point P1.

In the example illustrated in FIG. 5, standby command information indicating that the section control device 15 has given a standby command to the transport vehicle V is recorded as recording information M3 in association with point identification information Fp on the first stop point Ps1. Further, passage permission information Fa indicating that the section control device 15 has given passage permission to the transport vehicle V is recorded as recording information M4 in association with the point identification information Fp on the first passage point P1.

In the present embodiment, in a case where the section control device 15 gives passage permission to the transport vehicle V traveling along the second path R2 to pass through the second passage point P2, the section control device 15 records passage permission information Fa indicating that the passage permission has been given to the transport vehicle V, as recording information M in association with the second passage point P2. In the example illustrated herein, in a case where the section control device 15 gives passage permission to the transport vehicle V traveling along the second path R2 to pass through the second passage point P2, the section control device 15 records, as the recording information M, transport vehicle identification information Fv on the transport vehicle V receiving the passage permission and permission time information Ft indicative of a time when the passage permission has been given, in association with point identification information Fp on the second passage point P2.

In the example illustrated in FIG. 5, standby command information indicating that the section control device 15 has given a standby command to the transport vehicle V is recorded as recording information M5 in association with point identification information Fp on the second stop point Ps2. Further, passage permission information Fa indicating that the section control device 15 has given passage permission to the transport vehicle V is recorded as recording information M6 in association with point identification information Fp on the second passage point P2.

In the present embodiment, in a case where the section control device 15 gives passage permission to the transport vehicle V traveling from the first path R1 to the connection path D to pass through the second passage point P2, the section control device 15 records passage permission information Fa indicating that the passage permission has been given to the transport vehicle V, as recording information M, in association with both the first passage point P1 and the second passage point P2. In the specific section Za as described in the present embodiment, in a case where the transport vehicle V advances straight on the first path R1 or the second path R2, only passage permission for a corresponding path is just given to the transport vehicle V. However, in a case where the transport vehicle V passes through the connection path D, passage permission for both the first path R1 and the second path R2 is often given to the transport vehicle V to avoid interference with other transport vehicles V advancing straight on respective paths. In the present embodiment, in view of such a circumstance, the control state of the transport vehicle V in the specific section Za can be recorded appropriately as recording information M.

In the present embodiment, in a case where the section control device 15 gives passage permission to the transport vehicle V traveling from the first path R1 to the connection path D to pass through the second passage point P2, the section control device 15 records, as the recording information M, transport vehicle identification information Fv on the transport vehicle V receiving the passage permission and permission time information Ft indicative of a time when the passage permission has been given, in association with respective pieces of point identification information Fp on the first passage point P1 and the second passage point P2.

In the example illustrated in FIG. 5, standby command information indicating that the section control device 15 has given a standby command to the transport vehicle V is recorded as recording information M7 in association with the point identification information Fp on the first stop point Ps1. Further, passage permission information Fa indicating that the section control device 15 has given passage permission to the transport vehicle V is recorded as recording information M8 and recording information M9 in association with the respective pieces of point identification information Fp on the first passage point P1 and the second passage point P2.

In the present embodiment, in a case where the section control device 15 gives passage permission to the transport vehicle V to pass through the first passage point P1 and the second passage point P2, the abovementioned associated point information Fm is recorded as recording information M in association with point identification information Fp. With this configuration, the checking operation is easily performed in the superior control device 16 while the control state of the transport vehicle V at the first passage point P1 is compared with the control state of the transport vehicle V at the second passage point P2, the first passage point P1 and the second passage point P2 being related to each other.

In the present embodiment, the section control device 15 collectively transmits, to the superior control device 16, transmission information F obtained by gathering up all the pieces of recording information M recorded in association with the first passage point P1, and transmission information F obtained by gathering up all the pieces of recording information M recorded in association with the second passage point P2. With this configuration, the superior control device 16 can receive, at the same time, the control state of the transport vehicle V at the first passage point P1 and the control state of the transport vehicle V at the second passage point P2, the first passage point P1 and the second passage point P2 being related to each other. Accordingly, the checking operation is easily performed in the superior control device 16 while the control state of the transport vehicle V at the first passage point P1 is compared with the control state of the transport vehicle V at the second passage point P2, the first passage point P1 and the second passage point P2 being related to each other.

In the present embodiment, in a case where a first condition that the section control device 15 acquires no passage completion notice within a predetermined period after the transport vehicle V has been permitted to pass through a given recording point P is satisfied, the section control device 15 transmits transmission information F on the given recording point P satisfying the first condition to the superior control device 16. With this configuration, in a case where the transport vehicle V stops for a long time between the first stop point Ps1 and the first passage point P1 (or the second passage point P2) through which the transport vehicle V is permitted to pass, or in a case where the transport vehicle V deviates to a path that does not include the first passage point P1 (or the second passage point P2) through which the transport vehicle V is permitted to pass, for example, the section control device 15 can transmit, to the superior control device 16, transmission information F on the first passage point P1 (or the second passage point P2) through which the transport vehicle V is permitted to pass. Accordingly, it is possible to easily check the control state of the transport vehicle V in a case where the first condition is satisfied.

Whether or not the first condition is satisfied may be determined based on, for example, whether or not a period during which the section control device 15 receives no passage completion notice for the first passage point P1 and no passage completion notice for the second passage point P2 after passage permission information Fa associated with both the first passage point P1 and the second passage point P2 has been recorded as recording information M exceeds a predetermined period.

In the present embodiment, in a case where a second condition that a state where other transport vehicles V cannot pass through a given recording point P continues for a predetermined period is satisfied, the section control device 15 transmits transmission information F on the given recording point P satisfying the second condition to the superior control device 16. With this configuration, in a case where the transport vehicle V stops for a long time at the first stop point Ps1, for example, the section control device 15 can transmit, to the superior control device 16, transmission information F on the first passage point P1 (or the second passage point P2) through which the transport vehicle V is permitted to pass. Accordingly, it is possible to easily check the control state of the transport vehicle V in a case where the second condition is satisfied. The predetermined period in the first condition may be different from or may be the same as the predetermined period in the second condition. Further, the predetermined period in the first condition and the predetermined period in the second condition may vary in accordance with respective stop points or may be uniform in all the stop points. These predetermined periods are determined in accordance with a congestion state of the travel path R or a transport state of the article, for example.

Whether or not the second condition is satisfied may be determined based on, for example, whether or not an elapsed time from the standby start of the transport vehicle V at the first stop point Ps1 (or the second stop point Ps2), that is, a time recorded as the stopping time information Fs2, exceeds a predetermined time corresponding to the predetermined period. Further, for example, whether or not the second condition is satisfied may be determined based on whether or not a period during which the passage permission information Fa associated with the first passage point P1 (or the second passage point P2) is not recorded as the recording information M exceeds the predetermined period.

In the example illustrated in FIG. 4, standby command information indicating that the section control device 15 has given a standby command to the transport vehicle V is recorded as recording information M10, and passage permission information Fa indicating that the section control device 15 has given passage permission to the transport vehicle V is recorded as recording information M11 and recording information M12 in association with the respective pieces of point identification information Fp on the first passage point P1 and the second passage point P2. Further, in the example illustrated in FIG. 4, standby command information indicating that the section control device 15 has given a standby command to another transport vehicle V at the first stop point Ps1 is recorded as recording information M13 in association with the first stop point Ps1, and standby command information indicating that the section control device 15 has given a standby command to another transport vehicle V at the second stop point Ps2 is recorded as recording information M14 in association with the second stop point Ps2.

In the example illustrated in FIG. 4, in a case where the section control device 15 acquires no passage completion notice related to the first passage point P1 and no passage completion notice related to the second passage point P2, the section control device 15 generates transmission information F1 on the first passage point P1 by gathering up the recording information M8 and the recording information M11 and generates transmission information F2 on the second passage point P2 by gathering up the recording information M6, the recording information M9, and the recording information M12. Then, the section control device 15 collectively transmits the transmission information F1 and the transmission information F2 to the superior control device 16.

Further, in the example illustrated in FIG. 4, in a case where a state where other transport vehicles V cannot pass through the first stop point Ps1 or the second stop point Ps2 continues for a predetermined period, the section control device 15 generates transmission information F1 on the first passage point P1 by gathering up the recording information M8 and the recording information M11 and generates transmission information F2 on the second passage point P2 by gathering up the recording information M6, the recording information M9, and the recording information M12. Then, the section control device 15 collectively transmits the transmission information F1 and the transmission information F2 to the superior control device 16.

In the present embodiment, the section control device 15 is configured to transmit the transmission information F to the superior control device 16 at a given cycle. The given cycle is every 30 seconds, for example. Note that respective accumulation periods set for the plurality of recording points and the given period may be the same period.

In the present embodiment, in a case where the first condition is satisfied, the section control device 15 restricts the number of times to transmit the transmission information F to the superior control device 16 to a given number of times determined in advance. Further, in a case where the second condition is satisfied, the section control device 15 restricts the number of times to transmit the transmission information F to the superior control device 16 to a given number of times determined in advance. These given numbers of times determined in advance may be set to be the same given number of times for each of the plurality of recording points P or may be set to different numbers of times for each of the plurality of recording points P. With this configuration, it is possible to easily restrain pieces of transmission information F having similar contents from being transmitted several times in a case where a state where the first condition or the second condition is satisfied continues for a long time. The given number of times is three times, for example.

In the present embodiment, when the first condition and the second condition are not satisfied, the section control device 15 cancels the restriction on the number of times to transmit the transmission information F to the superior control device 16. Note that, in a case where the transmission information F includes pieces of recording information M with different pieces of transport vehicle identification information Fv after the number of times of transmission is restricted to the given number of times, the section control device 15 may be configured to permit transmission of the transmission information F to the superior control device 16.

### Other Embodiments

Next will be described other embodiments of the article transport facility 100.

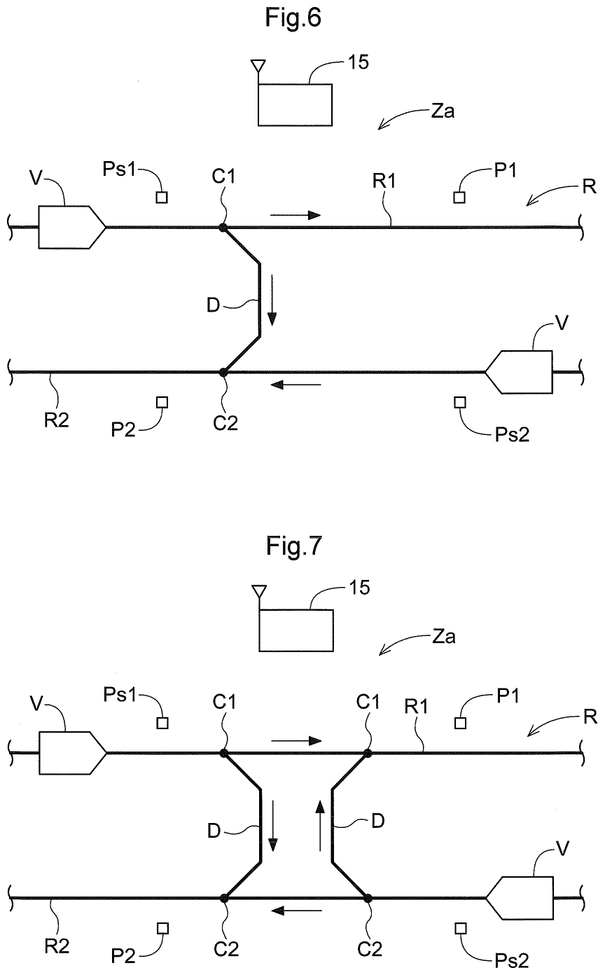

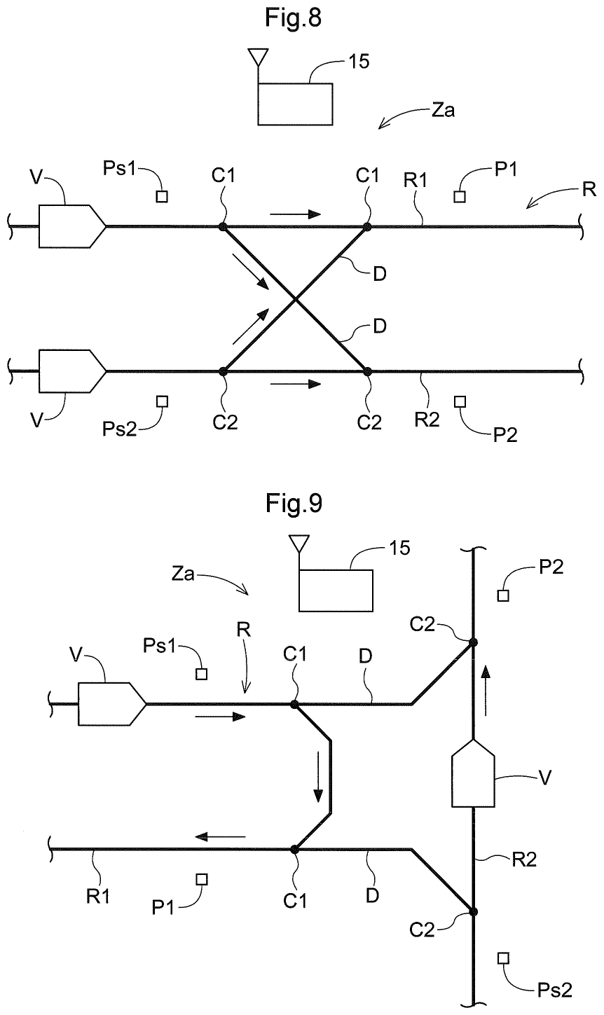

(1) The above embodiment has described, as an example, a configuration in which the first path R1, the second path R2, and the connection path D form an N-shape in a plan view. However, the present invention is not limited to such an example, and the connection path D may be disposed to be perpendicular to each of the first path R1 and the second path R2 disposed in parallel to each other in a plan view, for example. In this case, the first path R1, the second path R2, and the connection path D form an H-shape in a plan view. Further, the present invention is not limited to the above example, and the specific section Za can be set optionally. A given part of the travel path R may be set as the specific section Za, provided that the connection path D intersects with the first path R1 and the second path R2 in the given part. Further, as illustrated in FIGS. 6 to 9, for example, the connection path D may intersect with each of the first path R1 and the second path R2 at a given angle, or at least one of the three paths may curve. Further, a plurality of connection paths D may be connected to the first path R1 and the second path R2. Further, no connection path D may be provided in the travel path R where the transport vehicle V travels.

(2) The above embodiment has described, as an example, a configuration in which the section control device 15 records, as recording information M, point identification information Fp on the recording point P through which the transport vehicle V has been permitted to pass, in association with transport vehicle identification information Fv and permission time information Ft. However, the present invention is not limited to such an example, and the section control device 15 may be configured, for example, to record, as recording information M, time information on a standby command time at which the section control device 15 has given a standby command to the transport vehicle V, a passage request time at which the section control device 15 has acquired a passage request from the transport vehicle V, a passage completion time at which the section control device 15 has acquired a completion notice, and the like, in association with the point identification information Fp.

(3) The above embodiment has described, as an example, a configuration in which, in a case where passage permission is given to the transport vehicle V traveling from the first path R1 to the connection path D to pass through the second passage point P2, passage permission information Fa is recorded as recording information M in association with both the first passage point P1 and the second passage point P2, and transmission information F1 obtained by gathering up all pieces of recording information M recorded in association with the first passage point P1, and transmission information F2 obtained by gathering up all pieces of recording information M recorded in association with the second passage point P2 are collectively transmitted to the superior control device 16. However, the present invention is not limited to such an example, and the transmission information F1 and the transmission information F2 may be transmitted to the superior control device 16 separately, for example. Further, in a case where passage permission is given to the transport vehicle V traveling from the first path R1 to the connection path D to pass through the second passage point P2, passage permission information Fa may be recorded as recording information M in association with only the second passage point P2.

(4) The above embodiment has described, as an example, a configuration in which, in a case where the transport vehicle V has passed through the recording point P, the section control device 15 acquires a passage completion notice from the transport vehicle V. However, the present invention is not limited to such an example, and the section control device 15 may be configured not to acquire a passage completion notice, for example.

(5) The above embodiment has described, as an example, a configuration in which an accumulation period is set for each of the plurality of recording points P, and transmission information F is generated by gathering up pieces of recording information M every time the accumulation period elapses. However, the present invention is not limited to such an example, and transmission information F may be generated by gathering up pieces of recording information M when the number of pieces of recording information M reaches a predetermined number, for example.

(6) The above embodiment has described, as an example, a configuration in which, in a case where the first condition or the second condition is satisfied, the section control device 15 transmits transmission information F on the recording point P satisfying the first condition or the second condition to the superior control device 16. However, the present invention is not limited to such an example, and the section control device 15 may be configured to transmit the transmission information F to the superior control device 16 at a given cycle regardless of other conditions. Further, instead of transmitting the transmission information F at a given cycle, the section control device 15 may be configured to generate transmission information F and transmit it to the superior control device 16 only at the time when an operator who performs the checking operation gives a request. Further, in a case where the first condition or the second condition is satisfied, the transmission information F may be transmitted to the superior control device 16 at a given cycle.

(7) Note that the configuration disclosed in the above embodiment can be applied in combination with the configurations disclosed in other embodiments as long as no inconsistency occurs. In terms of other configurations, the embodiment disclosed in the present specification is also just an example in all respects. Accordingly, various modifications can be made appropriately as far as it does not deviate from the scope of this disclosure.

### Overview of Embodiment

The following describes the article transport facility described above.

An article transport facility according to this disclosure is an article transport facility including: at least one transport vehicle configured to transport an article; a travel path on which the at least one transport vehicle travels, the travel path being divided into a plurality of control regions; a plurality of section control devices each provided for a corresponding control region out of the plurality of control regions and configured to control passage of the at least one transport vehicle in the corresponding control region; and a superior control device configured to control the plurality of section control devices. The travel path includes a plurality of recording points. The plurality of section control devices are each configured to (i) record a control state of the at least one transport vehicle at each recording point in the corresponding control region as recording information associated with the each recording point, (ii) generate transmission information including a plurality of pieces of the recording information for the each recording point, and (iii) transmit to the superior control device the transmission information by the each recording point.

In this configuration, the section control device gathers up control states in the whole control region controlled by itself for each recording point to generate transmission information and transmits the transmission information to the superior control device per recording point. With this configuration, information to be received on the superior control device side is information collective per recording point, so that the control state of the transport vehicle at each recording point is easily checked in the superior control device. Further, it is possible to restrain the amount of information transmitted and received at a time between the section control device and the superior control device, thereby making it possible to reduce a burden to a communication line.

As one aspect, it is preferable that: the at least one transport vehicle includes a plurality of transport vehicles each having unique transport vehicle identification information, each of the plurality of recording points have unique point identification information, and in response to the plurality of section control devices each permitting a transport vehicle to pass through a recording point, the section control device record, as the recording information, point identification information on the recording point in association with (i) the transport vehicle identification information on the transport vehicle and (ii) permission time information indicative of a time point at which the section control device permitted the transport vehicle to pass.

With this configuration, transport vehicle identification information and permission time information can be transmitted to the superior control device in association with each other for each recording point through which the transport vehicle has been permitted to pass.

As one aspect, it is preferable that: each of the plurality of control regions include a specific section, the specific section include: a first path and a second path not intersecting with each other; and a connection path connecting a first connecting part in the first path to a second connecting part in the second path, the specific section includes a first passage point downstream from the first connecting part as a recording point, the specific section includes a second passage point downstream from the second connecting part as a recording point, in response to the plurality of section control devices each permitting a transport vehicle traveling on the first path for passage through the first passage point to pass through the first passage point, the section control device record, as the recording information, (i) the transport vehicle identification information on the transport vehicle and (ii) permission time information indicative of a time point at which the section control device permitted the transport vehicle to pass, in association with point identification information on the first passage point, in response to the plurality of section control devices each permitting a transport vehicle traveling on the second path for passage through the second passage point to pass through the second passage point, the section control device record, as the recording information, (i) the transport vehicle identification information on the transport vehicle and (ii) permission time information indicative of a time point at which the section control device permitted the transport vehicle to pass, in association with point identification information on the second passage point, and in response to the plurality of section control devices each permitting a transport vehicle traveling from the first path to the connection path for passage through the second passage point to pass through the second passage point, the section control device record, as the recording information, (i) the transport vehicle identification information on the transport vehicle and (ii) permission time information indicative of a time point at which the section control device permitted the transport vehicle to pass, in association with point identification information on the first passage point and point identification information on the second passage point.

In such a specific section, in a case where the transport vehicle advances straight on the first path or the second path, only passage permission for a corresponding path is just given to the transport vehicle. However, in a case where the transport vehicle passes through the connection path, passage permission for both the first path and the second path is often given to the transport vehicle to avoid interference with other transport vehicles advancing straight on respective paths. With the above configuration, in view of such a circumstance, the control state of the transport vehicle in the specific section can be recorded appropriately as recording information.

As one aspect, it is preferable that: each of the plurality of control regions include a specific section, the specific section include: a first path and a second path not intersecting with each other; and a connection path connecting a first connecting part in the first path to a second connecting part in the second path, the specific section includes a first passage point downstream from the first connecting part as a recording point, the specific section includes a second passage point downstream from the second connecting part as a recording point, and in response to the plurality of section control devices each permitting a transport vehicle traveling from the first path to the connection path for passage through the second passage point to pass through the second passage point, the section control device record, as the recording information, passage permission information indicating the section control device permitted the transport vehicle to pass, in association with the first passage point and the second passage point.

In such a specific section, in a case where the transport vehicle advances straight on the first path or the second path, only passage permission for a corresponding path is just given to the transport vehicle. However, in a case where the transport vehicle passes through the connection path, passage permission for both the first path and the second path is often given to the transport vehicle to avoid interference with other transport vehicles advancing straight on respective paths. With the above configuration, in view of such a circumstance, the control state of the transport vehicle in the specific section can be recorded appropriately as recording information.

As one aspect, it is preferable that the plurality of section control devices each collectively transmit, to the superior control device, transmission information including recording information recorded in association with the first passage point, and transmission information including recording information recorded in association with the second passage point.

With this configuration, it is possible to easily perform a checking operation in the superior control device while the control state of the transport vehicle at the first passage point is compared with the control state of the transport vehicle at the second passage point, the first passage point and the second passage point being related to each other.

As one aspect, it is preferable that: each of the plurality of recording points has an accumulation period, and the plurality of section control devices each generate transmission information including recording information on each recording point for the accumulation period, and transmit the transmission information to the superior control device.

With this configuration, it is possible for the superior control device to automatically acquire the transmission information continuously. Further, since the accumulation period as a sign to transmit transmission information is set for each of the plurality of recording points, the transmission information is easily transmitted to the superior control device at respective different timings of the plurality of recording points. Accordingly, it is possible to restrain the amount of information transmitted and received at a time between the section control device and the superior control device.

As one aspect, it is preferable that: the plurality of section control devices are each configured to receive a passage completion notice in response to a transport vehicle having passed a recording point, and the plurality of section control devices each transmit, to the superior control device, transmission information on a recording point satisfying either a first condition or a second condition, the first condition being that the section control device does not receive the passage completion notice within a predetermined time period after the section control device permitted the transport vehicle to pass through the recording point, the second condition being that another transport vehicle has been unable to pass through the recording point for a predetermined time period.

With this configuration, in a case where no passage completion notice is acquired within a predetermined period, or in a case where a problem that a state where other transport vehicles cannot pass through a recording point continues for a predetermined period occurs, it is possible to transmit, to the superior control device, transmission information on the recording point having such a problem. Accordingly, it is possible to easily check the control state of the transport vehicle in a case where the problem occurs.

As one aspect, it is preferable that: the plurality of section control devices are each configured to transmit the transmission information to the superior control device at a predetermined cycle, and the section control device transmits the transmission information to the superior control device up to predetermined times in response to the first condition or the second condition being satisfied.

With this configuration, it is possible to easily restrain pieces of transmission information having similar contents from being transmitted several times in a case where a state where the first condition or the second condition is satisfied continues for a long time, for example.

What is claimed is:

1. An article transport facility, comprising:
at least one transport vehicle configured to transport an article;
a travel path on which the at least one transport vehicle travels, the travel path divided into a plurality of control regions;
a plurality of section control devices each provided for a corresponding control region out of the plurality of control regions and configured to control passage of the at least one transport vehicle in the corresponding control region;
a superior control device configured to control the plurality of section control devices;
the travel path including a plurality of recording points; and
the plurality of section control devices each configured to (i) record a control state of the at least one transport vehicle at each recording point in the corresponding control region as recording information associated with said each recording point, (ii) generate transmission information including a plurality of pieces of the recording information for said each recording point, and (iii) transmit the transmission information to the superior control device by said each recording point.

2. The article transport facility according to claim 1, wherein:
the at least one transport vehicle comprises a plurality of transport vehicles each having unique transport vehicle identification information,
each of the plurality of recording points has unique point identification information, and
in response to the plurality of section control devices each permitting a transport vehicle to pass through a recording point, the section control device records, as the recording information, point identification information on the recording point in association with (i) the transport vehicle identification information on the transport vehicle and (ii) permission time information indicative of a time point at which the section control device permitted the transport vehicle to pass.

3. The article transport facility according to claim 2, wherein:
each of the plurality of control regions includes a specific section,
the specific section includes:
a first path and a second path not intersecting with each other; and
a connection path connecting a first connecting part in the first path to a second connecting part in the second path,
the specific section includes a first passage point downstream from the first connecting part as a recording point,
the specific section includes a second passage point downstream from the second connecting part as a recording point,
in response to the plurality of section control devices each permitting a transport vehicle traveling on the first path for passage through the first passage point to pass through the first passage point, the section control device records, as the recording information, (i) the transport vehicle identification information on the transport vehicle and (ii) permission time information indicative of a time point at which the section control device permitted the transport vehicle to pass, in association with point identification information on the first passage point,
in response to the plurality of section control devices each permitting a transport vehicle traveling on the second path for passage through the second passage point to pass through the second passage point, the section control device records, as the recording information, (i) the transport vehicle identification information on the transport vehicle and (ii) permission time information indicative of a time point at which the section control device permitted the transport vehicle to pass, in association with point identification information on the second passage point, and
in response to the plurality of section control devices each permitting a transport vehicle traveling from the first path to the connection path for passage through the second passage point to pass through the second passage point, the section control device records, as the recording information, (i) the transport vehicle identification information on the transport vehicle and (ii) permission time information indicative of a time point at which the section control device permitted the transport vehicle to pass, in association with point identification information on the first passage point and point identification information on the second passage point.

4. The article transport facility according to claim 1, wherein:
each of the plurality of control regions includes a specific section,
the specific section includes:
a first path and a second path not intersecting with each other; and
a connection path connecting a first connecting part in the first path to a second connecting part in the second path,
the specific section includes a first passage point downstream from the first connecting part as a recording point,
the specific section includes a second passage point downstream from the second connecting part as a recording point, and
in response to the plurality of section control devices each permitting a transport vehicle traveling from the first path to the connection path for passage through the second passage point to pass through the second passage point, the section control device records, as the recording information, passage permission information indicating that the section control device permitted the transport vehicle to pass, in association with the first passage point and the second passage point.

5. The article transport facility according to claim 4, wherein:
the plurality of section control devices each collectively transmit, to the superior control device, transmission information including recording information recorded in association with the first passage point and transmission information including recording information recorded in association with the second passage point.

6. The article transport facility according to claim 1, wherein:
each of the plurality of recording points has an accumulation period, and
the plurality of section control devices each generate transmission information including recording information on each recording point for the accumulation period, and transmit the transmission information to the superior control device.

7. The article transport facility according to claim 1, wherein:
the plurality of section control devices are each configured to receive a passage completion notice in response to a transport vehicle having passed a recording point, and
the plurality of section control devices each transmit, to the superior control device, transmission information on a recording point satisfying either a first condition or a second condition, the first condition being that the section control device does not receive the passage completion notice within a predetermined time period after the section control device permitted the transport vehicle to pass through the recording point, the second condition being that another transport vehicle has been unable to pass through the recording point for a predetermined time period.

8. The article transport facility according to claim 7, wherein:
the plurality of section control devices are each configured to transmit the transmission information to the superior control device at a predetermined cycle, and
the section control device transmits the transmission information to the superior control device up to predetermined times in response to the first condition or the second condition being satisfied.
